(19) United States
(12) Patent Application Publication
(10) Pub. No.: US 2026/0343772 A1
(43) Pub. Date: Oct. 29, 2026

(54) MODULE EDGE INTERFACE ASSEMBLY LOCATING

(71) Applicant: Molex, LLC, Lisle, IL (US)

(72) Inventors: Gianni Ryan Bardella, Maumelle, AR (US); Arturo Casares Valdes, Conway, AR (US)

(21) Appl. No.: 19/447,005

(22) Filed: Jan. 13, 2026

Related U.S. Application Data
(60) Provisional application No. 63/744,872, filed on Jan. 14, 2025.

(51) Int. Cl. H05K 7/14; H01R 12/72; H01R 12/75; H05K 1/11

(52) U.S. Cl. CPC H05K 7/142; H01R 12/721; H01R 12/75; H05K 1/117; H05K 2201/09163

(57) ABSTRACT

Techniques for precisely locating signal contacts on card edge interfaces are described. An example cable assembly includes a housing with a datum pillar positioned along a side wall of the housing. The datum pillar includes a locating ridge extending from an outer surface of the datum pillar. A printed circuit board (PCB) in the cable assembly includes an interlock notch. The datum pillar of the housing occupies open space within the interlock notch of the PCB, and the locating ridge of the datum pillar sets or determines a location of the PCB with respect to the housing. The locating ridge sets the location of the PCB based on a mechanical interference between the locating ridge and a peripheral edge of the interlock notch of the PCB. The locating ridge also sets a location of a leading contact edge of a signal contact on a front edge of the PCB.

### BACKGROUND

The amount of data processed by computers, computing systems, and computing environments continues to increase. For example, data centers can include hundreds of computing and networking systems interconnected using optical cables, copper cables, and various connectors, cable assemblies, and terminations between them. The data throughput of these interconnects is high and increasing. As examples, many data centers incorporate a combination of 10 Gigabit Ethernet (10 GbE), 25 GbE, 50 GbE, and 100 GbE network interfaces and interconnects. 200 GbE, 400 GbE, and 800 GbE interconnection technology is also being developed and deployed. Other interconnection solutions rely upon 56 Gigabit per second (Gb/s), 112 Gb/s, and 224 Gb/s interconnection technologies, and interconnection technologies are being developed to support higher data rates. A range of cable assemblies are available for the data interconnects. A variety of designs exist for each cable assembly, depending on the requirements of the data communications environment in which the connectors are used.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

New assemblies and assembly techniques for locating signal contacts on card edge or PCB-style tip interfaces with improved accuracy are described. The concepts can be applied to SFP modules, and example SFP modules incorporating the techniques for precisely locating signal contacts are described herein. It should be appreciated, however, that the concepts can be extended to a wide range of cable assemblies, termination assemblies, and other assemblies for data communications.

An example cable assembly includes a housing with a datum pillar. The datum pillar includes a locating ridge extending from an outer surface of the datum pillar. The cable assembly also includes a printed circuit board (PCB) positioned in the housing. The PCB includes an interlock notch. The datum pillar occupies open space within the interlock notch of the PCB, when the PCB is seated into the housing. The locating ridge of the datum pillar applies a mechanical interference to a peripheral edge of the interlock notch of the PCB. In one aspect, the PCB includes a row of contacts, the row of contacts includes signal contacts and ground contacts, a signal contact among the row of contacts includes a leading contact edge, and the locating ridge of the datum pillar sets a location of the leading contact edge of the signal contact with respect to a datum surface of the datum pillar.

The locating ridge includes an angled central edge and a vertical central edge in one example. The vertical central edge extends up from a seating surface of the housing, and the angled central edge extends at an angle from the vertical central edge to a surface of the datum pillar. The locating ridge includes an angled central edge and a vertical central surface in another example. The datum pillars can also include centering bumpers that extend from outer surfaces of the datum pillars in some examples.

In other aspects, the housing further includes an upper housing shell and a lower housing shell, and the lower housing shell includes a bottom wall and side walls that extend perpendicular to the bottom wall. The datum pillar can be positioned along a side wall among the side walls of the lower housing shell. In one example, the datum pillar is a first datum pillar positioned along a first side wall of the housing, and the locating ridge is a first locating ridge that extends from an outer surface of the first datum pillar. The housing may also include a second datum pillar positioned along a second side wall of the housing, and a second locating ridge extends from an outer surface of the second datum pillar.

In other aspects, the housing further includes an upper housing shell and a lower housing shell, and the lower housing shell includes a bottom wall and side walls that extend perpendicular to the bottom wall. The datum pillar can be positioned along a side wall among the side walls of the lower housing shell. In one example, the datum pillar is a first datum pillar positioned along a first side wall of the housing, and the locating ridge is a first locating ridge that extends from an outer surface of the first datum pillar. The housing may also include a second datum pillar, and a bumper may extend from an outer surface of the second datum pillar.

In other aspects, the interlock notch of the PCB may be a first interlock notch positioned along a first peripheral side edge of the PCB. The PCB may include a second interlock notch positioned along a second peripheral side edge of the PCB. The first locating ridge and the second locating ridge can set the location of the PCB with respect to the housing based on a mechanical interference between the first locating ridge and the first interlock notch and a mechanical interference between the second locating ridge and the second interlock notch.

In other aspects, the interlock notch of the PCB may be a first interlock notch positioned along a peripheral side edge of the PCB. The PCB may include a second interlock notch positioned along the peripheral side edge of the PCB. The first locating ridge and the second locating ridge can set the location of the PCB with respect to the housing based on a mechanical interference between the first locating ridge and the first interlock notch and a mechanical interference between the second locating ridge and the bumper.

Another example cable assembly includes a housing with a datum surface and a locating ridge, and a PCB positioned in the housing. The locating ridge can set a location of the PCB with respect to the datum surface of the housing based on contact between the locating ridge and a peripheral edge of the PCB. The PCB includes a signal contact in one example, and the locating ridge can set a location of a leading contact edge of the signal contact with respect to the datum surface. The locating ridge can include an angled central edge and a vertical central edge in one case. The vertical central edge can extend up from a seating surface of the housing and the angled central edge can extend at an angle from the vertical central edge. The locating ridge includes an angled central edge and a vertical central surface in another example.

Another example cable assembly includes a housing with a locating ridge and a centering bumper, and a PCB positioned in the housing. The locating ridge and the centering bumper can set a location of the PCB with respect to the housing based on contact between a peripheral edge of the PCB, the locating ridge, and the centering bumper. The PCB includes a signal contact, and the locating ridge can set a location of a leading contact edge of the signal contact with respect to a datum surface of the housing.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1A illustrates a perspective view of one end of a cable assembly according to aspects of the present disclosure.

FIG. 1B illustrates a perspective view of the cable assembly shown in FIG. 1A, with the housing expanded, according to aspects of the present disclosure.

FIG. 2A illustrates a perspective view of the front end of the module of the cable assembly shown in FIG. 1A, with the upper housing shell omitted, according to aspects of the present disclosure.

FIG. 2B illustrates a top-down view of the front end of the cable assembly shown in FIG. 1A, with the top housing shell omitted, according to aspects of the present disclosure.

FIG. 3 illustrates a top-down view of the front end of the PCB in the cable assembly shown in FIG. 1A according to aspects of the present disclosure.

FIGS. 4A and 4B illustrate detail views of one side of the lower housing shell of the cable assembly shown in FIG. 1A according to aspects of the present disclosure.

FIGS. 4C and 4D illustrate detail views of another SIDE of the lower housing shell of the cable assembly shown in FIG. 1A according to aspects of the present disclosure.

FIG. 5 illustrates a detail view of another example locating ridge of a housing according to aspects of the present disclosure.

FIG. 6 illustrates the sectional view of the cable assembly designated A-A in FIG. 2B according to aspects of the present disclosure.

FIG. 7 illustrates another example lower housing shell of the cable assembly shown in FIG. 1A according to aspects of the present disclosure.

### DETAILED DESCRIPTION

The amount of data processed by computers, computing systems, and computing environments continues to increase. For example, data centers can include hundreds of computing and networking systems interconnected using optical cables, copper cables, and various connectors, cable assemblies, and terminations between them.

The small form-factor pluggable (SFP) module format is a compact, hot-pluggable network interface module format used for data interconnects, and SFP modules are commonly used for interconnects in data centers. An SFP interface on a computing or networking system is a modular slot for a media-specific transceiver, such as a fiber-optic or a copper cable assembly. Cable assemblies can include SFP pluggable transceiver modules at one or both ends of a copper, fiber-optic, or other type of interconnecting cable. SFP pluggable transceiver modules can be inserted into SFP interfaces for data interconnections.

A range of SFP pluggable transceiver modules are currently available, including small form-factor pluggable double density (SFP-DD), compact small form-factor pluggable (cSFP), SFP+, quad small form-factor pluggable (QSFP), quad small form-factor pluggable double density (QSFP-DD), octal small form factor pluggable (OSFP), and others. SFP pluggable transceiver modules often include one or more printed circuit boards (PCBs) with one or more semiconductor circuit devices or chips and other circuitry mounted to the PCB. An active electrical cable (AEC) assembly can include one or more SFP pluggable transceiver modules at the free ends of cables or a cable bundle. An AEC assembly can include a PCB and semiconductor chips for signal re-timing, noise reduction, signal integrity improvement, and other functions. Other types of cable assemblies, including passive cable assemblies, can also include PCBs within housings of pluggable modules.

In the context outlined above, new approaches, assemblies, and assembly techniques for locating signal contacts on card edge or PCB-style tip interfaces with improved accuracy are described herein. The concepts can be applied to SFP modules, and example SFP modules incorporating the techniques for precisely locating signal contacts are described herein. It should be appreciated, however, that the concepts can be extended to a wide range of cable assemblies, termination assemblies, and other assemblies for data communications.

An example cable assembly includes a housing with a datum pillar positioned along a side wall of the housing. The datum pillar includes a locating ridge extending from an outer surface of the datum pillar. A PCB in the cable assembly includes an interlock notch. The datum pillar of the housing can occupy open space within the interlock notch of the PCB, and the locating ridge of the datum pillar can set or determine a location of the PCB with respect to the housing. The locating ridge can set the location of the PCB based on a mechanical interference between the locating ridge and a peripheral edge of the interlock notch of the PCB. The locating ridge can also set a location of a leading contact edge of a signal contact on a front edge of the PCB.

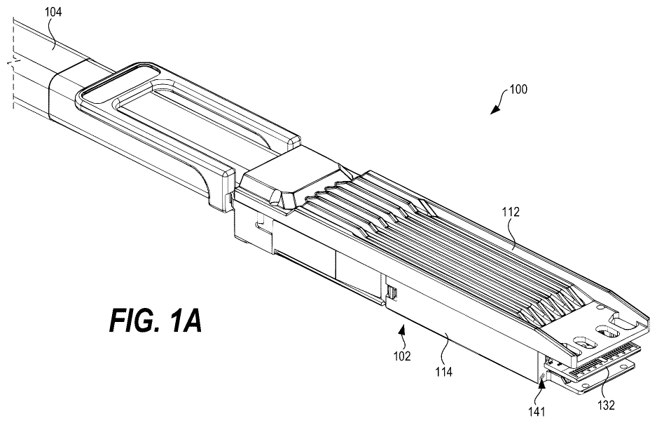

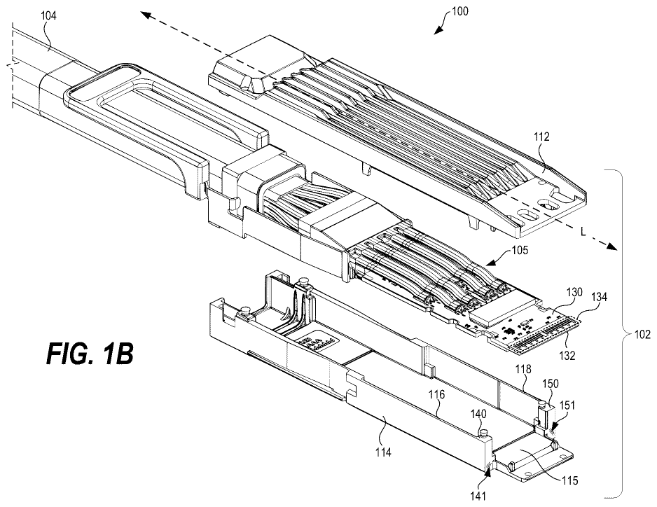

Turning to the drawings, FIG. 1A illustrates a perspective view of one end of a cable assembly 100. FIG. 1B illustrates a perspective view of the cable assembly 100, with a housing of the cable assembly 100 expanded. The cable assembly 100 is representative, not drawn to any particular size or scale, and is illustrated to provide an example of a module that incorporates features for precisely locating signal contacts on PCBs. The cable assembly 100 is not intended to be limited to any particular style or type of cable or cable assembly. The concepts of precisely locating signal contacts on PCBs, as described herein, are also not limited to use with SFP modules. The concepts can be relied upon in a wide range of cable assemblies, termination assemblies, and other assemblies for data communications.

The cable assembly 100 includes a pluggable transceiver module 102 (also “module 102”) at one end of a cable bundle 104. The cable assembly 100 is an example of an AEC or related type of cable assembly. The module 102, which is described in further detail below, is also representative, and the concepts described herein can be applied to a range of pluggable modules, including SFP, OSFP, SFP-DD, cSFP, SFP+, QSFP, QSFP-DD, and other types of pluggable modules.

Referring between FIGS. 1A and 1B, the module 102 includes a housing or module shell that encloses a number of components, such a PCB 130, one or more semiconductor chips and other circuitry mounted on the PCB 130, and other components. The module 102 is illustrated as an example in FIGS. 1A and 1B. In other cases, other housings of related modules can enclose two or more PCBs and other components, and the concepts described herein can be extended to other types of modules and related assemblies. The housing includes an upper housing shell 112 and a lower housing shell 114 in FIGS. 1A and 1B. The upper housing shell 112 and the lower housing shell 114 of the housing can be embodied as or formed from a metal or metal alloy, although other types of materials can also be relied upon. In one example, the upper housing shell 112 and lower housing shell 114 can be embodied as a die-cast zinc, zinc alloy, or other metals or metal alloys and can be plated in some cases. The housing of the module 102 can be formed using any suitable additive or subtractive manufacturing techniques, including cutting, stamping, bending, molding, injection molding, printing, and other techniques.

The cable bundle 104 includes a number of cables with signal, ground, and/or drain conductors. In one example, the cable bundle 104 includes a number of twinaxial or twinax cables 105 (also “cables 105”). The cable bundle 104 can be embodied by cables other than twinax cables in some cases, including twisted pair cables, shielded twisted pair cables, single-conductor cables, shielded single-conductor cables, single-conductor coaxial cables, and other types of cables. Each of the cables 105 can include a pair of signal conductors surrounded by a dielectric insulator or insulating material, a shield, one or more drain or ground conductors, and a jacket. The signal conductors of the cables 105 can be electrically coupled and terminated to signal and drain contact pads on the PCB 130. The ground or drain conductors of the cables 105 can also be electrically coupled and terminated to ground contact pads or surface regions of the PCB 130.

The PCB 130 can be embodied as a printed circuit board including a laminated stack of metal layers and dielectric insulating material or like substrate. One or more semiconductor chips and other circuit components can be electrically coupled to and mounted on the PCB 130. The circuit components can be electrically interconnected among each other by metal traces of the PCB 130. The PCB 130 includes a PCB-style tip or card edge interface at a front edge 132 of the PCB 130. Data signals carried over the cables 105 can be routed on the metal traces of the PCB 130, among the semiconductor chips and other circuit components on the PCB 130 for signal processing, and to and from the row of contacts 134 on the card edge interface at the front edge 132 of the PCB 130. The row of contacts 134 extends on a top surface of the PCB 130 toward the front edge 132. The row of contacts 134 can include a combination of high-speed signal contacts, low-speed signal contacts, power contacts, drain or ground contacts, and other contacts. The PCB 130 can also include another row of contacts similar to the row of contacts 134, extending on a bottom surface of the PCB 130.

The module 102 includes a front port end and a cable opening end. A longitudinal axis “L” extends from the front port end to the cable opening end of the module 102. The longitudinal axis “L” also extends along the upper housing shell 112, the lower housing shell 114, and the PCB 130, from the front port end to the cable opening end of the module 102. The cable bundle 104 extends out from the cable opening end of the module 102. The front edge 132 of the PCB 130 extends out from the front port end of the module 102. As noted above, the pluggable module 102 is an example of an SFP module, and the module 102 can be inserted into a port (not shown) for data communication with another computing or networking device. The front port end of the module 102 can be inserted into the port. Electrical connections can be established between a mating connector within the port and the row of contacts 134 at the front edge 132 of the PCB 130.

It can be important for the module 102 to be designed and assembled with relatively high precision and tight tolerances, particularly if the module 102 is used for high data rate applications. Newer industry standard specifications for high data rate SFP modules may define tolerances for the positions of contacts in the row of contacts 134 based on electrical, mechanical, or related performance requirements for such data rates. As one example, when the module 102 is inserted into a port, the positions of the contacts in the row of contacts 134, with respect to the mating connector within the port, can be defined by industry standards and important for high data rate communication. As an example standard specification, the positions of the signal contacts in the row of contacts 134 can be specified between the leading edge of the contacts and one or more datum surfaces of the housing shell, as described in further detail below.

The lower housing shell 114 includes a bottom wall 115 and side walls 116 and 118. The side walls 116 and 118 extend in a direction (and in separate planes) perpendicular to the bottom wall 115. As shown in FIG. 1B, a datum pillar 140 is positioned at one end of the side wall 116, toward the front port end of the module 102. A datum pillar 150 is also positioned at one end of the side wall 118, toward the front port end of the module 102. The size, shape, and positions of the datum pillars 140 and 150 can vary in other embodiments as compared to that shown. The lower housing shell 114 can also include other datum pillars, at other locations, in addition to the datum pillars 140 and 150. The positions of the contacts in the row of contacts 134 of the PCB 130 can be specified between the leading edge of the contacts and datum surfaces 141 and 151 of the datum pillars 140 and 150, respectively, as described in further detail below. The datum pillars 140 and 150, locating ridges on the datum pillars 140 and 150, centering bumpers on the datum pillars 140 and 150, and other features of the module 102 are designed to ensure the position of the row of contacts 134 of the PCB 130 with precision, as described in further detail below. The locating ridges, centering bumpers, and other features can be formed on a combination of the datum pillars 140 and 150 and other datum pillars of the lower housing shell 114. A range of different examples are described below.

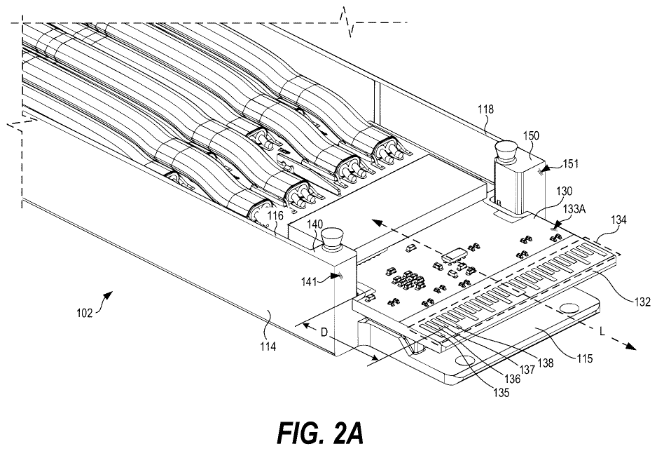

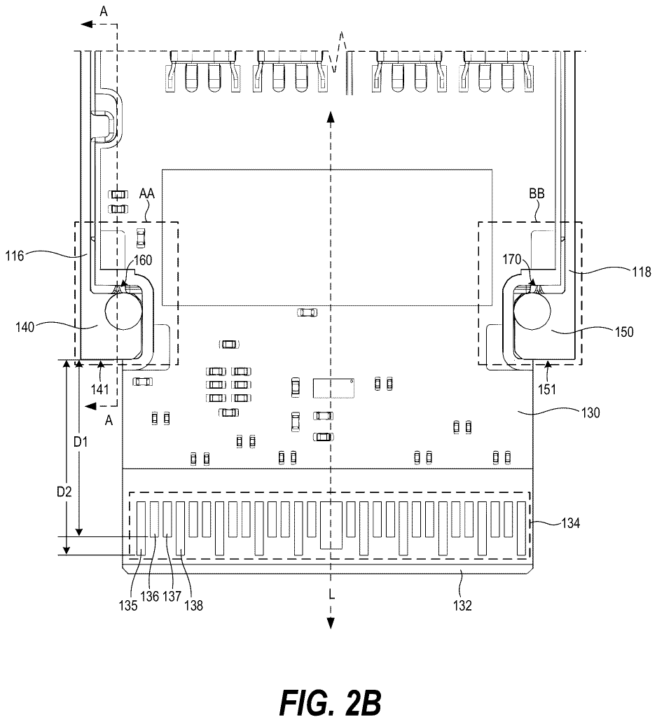

FIG. 2A illustrates a perspective view of the front end of the module 102 of the cable assembly 100 shown in FIG. 1A, with the lower housing shell 114 omitted. FIG. 2B illustrates a top-down view of the front end of the of the module 102 with the lower housing shell 114 omitted. Thus, FIGS. 2A and 2B illustrate the PCB 130 and the lower housing shell 114. The lower housing shell 114 includes a bottom wall 115 and side walls 116 and 118. A datum pillar 140 is positioned at one end of the side wall 116, toward the front port end of the module 102. The datum pillar 140 can be integrally formed with the side wall 116 as part of the side wall 116, as one example, although the datum pillar 140 can also be a separate component of the module 102. A datum pillar 150 is also positioned at one end of the side wall 118, toward the front port end of the module 102. The datum pillar 150 can be integrally formed with the side wall 118 as part of the side wall 118, as one example, although the datum pillar 150 can also be a separate component of the module 102. The size, shape, number, and positions of the datum pillars 140 and 150 can vary in other embodiments as compared to that shown in FIG. 2A.

The PCB 130 is positioned and secured in the lower housing shell 114 of the housing. One or more semiconductor chips and other circuit components are mounted on and electrically coupled to the PCB 130 in the example shown in FIG. 2A. The PCB 130 includes a PCB-style tip or card edge interface at a front edge 132 of the PCB 130. Data signals can be routed through the PCB 130 and to and from the row of contacts 134 on the card edge interface at the front edge 132 of the PCB 130. The row of contacts 134 extends on a top surface 133A of the PCB 130 toward the front edge 132. The row of contacts 134 can include a combination of high-speed signal contacts, low-speed signal contacts, power contacts, drain or ground contacts, and other contacts. The row of contacts 134 is depicted as a representative example. The concepts described herein can be applied to set or control the position of the row of contacts 134 accurately, but the concepts can be relied upon to accurately position other rows of contacts, including larger and smaller rows of contacts, for other types and styles of pluggable modules, cable assemblies, termination assemblies, and related assemblies for data communications.

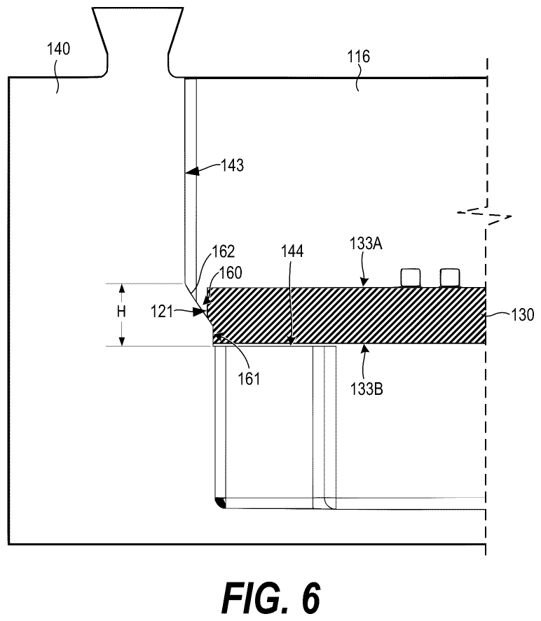

The contacts 135-138 of the PCB 130 are separately referenced in FIGS. 2A and 2B, as example contacts of the row of contacts 134. The contacts 135 and 138 are examples of ground or drain contacts among the row of contacts 134. The contacts 136 and 137 are examples of signal contacts among the row of contacts 134. A differential signal can be electrically communicated over the signal contacts 136 and 137. The ground contacts 135 and 138 can be relatively longer in the direction of the longitudinal axis “L” as compared to the signal contacts 136 and 137, so that the ground contacts 135 and 138 can electrically contact terminal pins in a mating connector before the signal contacts 136 and 137. The PCB 130 can also include another row of contacts similar to the row of contacts 134, extending on a bottom surface 133B (see FIG. 6) of the PCB 130.

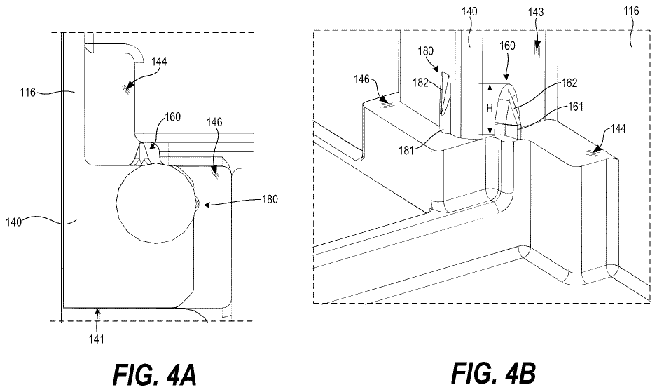

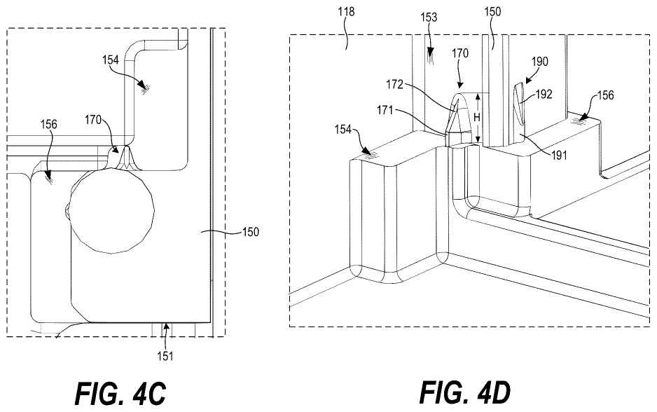

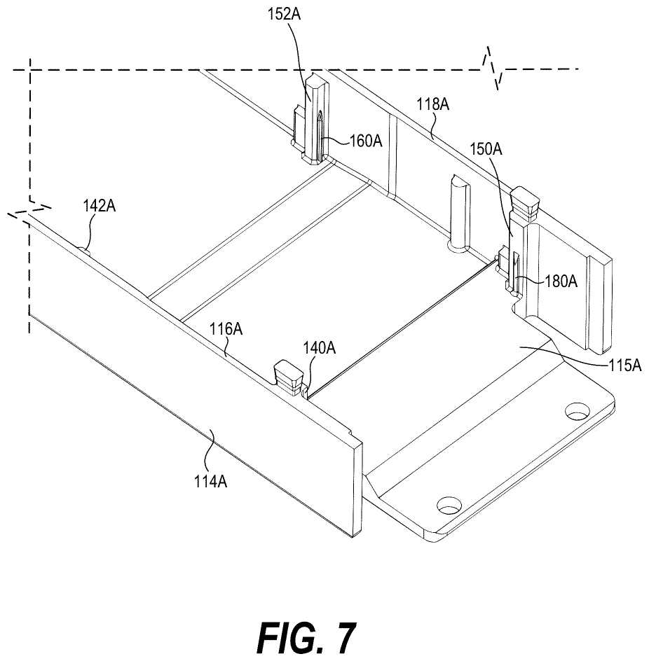

The PCB 130 includes one or more interlock notches formed along each side or side edge. The interlock notches of the PCB 130 are described in further detail below with reference to FIGS. 4A-4D. The datum pillars 140 and 150 of the lower housing shell 114 can occupy (e.g., fit within) the open space within the interlock notches of the PCB 130. The interlock notches can be sized and positioned to substantially conform to the geometry of the data pillars 140 and 150. A mechanical interference between the datum pillars 140 and 150 and the PCB 130 can accurately set or determine the position of the row of contacts 134 with respect to the housing of the module 102. More particularly, mechanical interferences between the edges of the interlock notches of the PCB 130 and locating ridges of the datum pillars 140 and 150 can set the positions of the contacts in the row of contacts 134 with respect to the datum surfaces 141 and 151 of the datum pillars 140 and 150. In other implementations, such as that described below with reference to FIG. 7, additional datum pillars of the lower housing shell can occupy the open space within other interlock notches of the PCB 130 or similar PCBs.

The positions of one or more signal contacts, such as one or both of the signal contacts 136 and 137, can be set with respect to the datum surfaces 141 and 151 based on the mechanical interferences. The leading edges of one or both of the signal contacts 136 and 137 can be accurately set to be the distance “D1 shown in FIG. 2B,” which is a measurement between the datum surfaces 141 and 151 of the datum pillars 140 and 150 and the leading edges of the signal contacts 136 and 137 based on the mechanical interference, to meet industry standard specifications or other criteria. In other cases, a specified distance similar to D1 can be measured between the datum surfaces 141 and 151 and the trailing edges of the contacts 136 and 137. As a different example, the positions of one or more ground or drain contacts, such as the ground contacts 135 and 138, can be set with respect to the datum surfaces 141 and 151. In that case, the leading edges of one or both of the ground contacts 135 and 138 can be accurately set to be the distance “D2,” which is a measurement between the datum surfaces 141 and 151 and the leading edges of the ground contacts 135 and 138. A specified distance similar to D2 can alternatively be measured between the datum surfaces 141 and 151 and the trailing edges of the ground contacts 135 and 138. Other dimensional specifications between surfaces of the housing of the module 102 and leading or trailing edges of contacts among the row of contacts 134 can also be designed-for based on the concepts described herein.

The PCB 130 can be manufactured to relatively tight tolerances. The housing of the module 102, including the lower housing shell 114, can also be manufactured to relatively tight tolerances. The PCB 130 should be accurately positioned within the lower housing shell 114, however, to maintain the value of “D” within a certain range. Thus, the locating ridges 160 and 170 of the datum pillars 140 and 150 can help to ensure an accurate position of the PCB 130 within the lower housing shell 114. When the PCB 130 is seated and assembled into the lower housing shell 114, the locating ridges 160 and 170 can push against the edges of the interlock notches of the PCB 130, setting the position of the PCB 130 accurately with respect to the lower housing shell 114. In turn, the leading edges of the contacts 136 and 137 in the row of contacts 134 can be accurately set to be the distance “D” from the datum surfaces 141 and 151 of the datum pillars 140 and 150. The locating ridges 160 and 170 and interlock notches of the PCB 130 are described in further detail below with reference to FIGS. 4A and 4B.

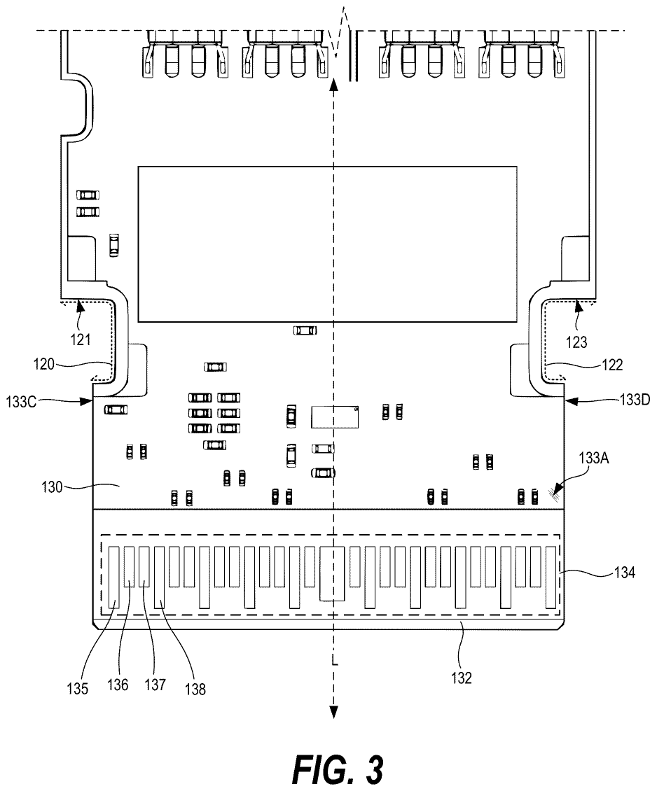

FIG. 3 illustrates a top-down view of the front end of the PCB 130. As best shown in FIG. 3, the PCB 130 includes an interlock notch 120 formed along the peripheral side edge 133C. The PCB 130 can also include an interlock notch 122 formed along the peripheral side edge 133D. The size, shape, and positions of the interlock notches 120 and 122 are provided as a representative example in FIG. 3. PCBs according to the concepts described herein can include other types, styles, shapes, and sizes of interlock notches for positioning purposes, consistent with the concepts described here.

An open space or region is provided within each of the interlock notches 120 and 122. When the PCB 130 is seated and assembled into the lower housing shell 114 (see FIG. 2A), the datum pillars 140 and 150 of the lower housing shell 114 occupy the space within the interlock notches 120 and 122, respectively. The interlock notch 120 is defined by the side edge 133C of the PCB 130. The locating edge 121 of the interlock notch 120 is part of the peripheral side edge 133C of the PCB 130. Similarly, the interlock notch 122 is defined by the side edge 133D of the PCB 130. The locating edge 123 of the interlock notch 122 is part of the peripheral side edge 133D of the PCB 130. The locating ridges 160 and 170 of the datum pillars 140 and 150 can push against the locating edges 121 and 123 of the interlock notches 120 and 122 of the PCB 130, to set the position of the PCB 130 accurately with respect to the lower housing shell 114. The locating ridges 160 and 170 may also prevent translation of the PCB 130 when the module 102 is inserted into or removed from an external connector.

FIG. 4A illustrates a top-down view of the detail view AA shown in FIG. 2B, and FIG. 4B illustrates a perspective view of the detail view AA shown in FIG. 2B. The PCB 130 is omitted from view in both FIGS. 4A and 4B, so that the locating ridge 160 can be shown. The locating ridge 160 is depicted as an example in FIGS. 4A and 4B, and the locating ridge 160 can vary in size, shape, and style in other embodiments and as described below. The locating ridge 160 can be formed as an angled ridge of material that extends outwardly from a surface of the datum pillar 140. The locating ridge 160 extends outwardly from a back surface 143 of the datum pillar 140. The back surface 143 of the datum pillar 140 extends in a plane that runs parallel to the datum surface 141 (see FIG. 2A) of the datum pillar 140.

The datum pillar 140 includes seating surfaces 144 and 146. A bottom surface of the PCB 130 can rest upon the seating surfaces 144 and 146 of the datum pillar 140, among other surfaces provided by the lower housing shell 114, when the PCB 130 is assembled in the module 102. The locating ridge 160 extends up to a height “H” from the seating surface 144. The locating ridge 160 includes a vertical (or substantially vertical) central edge 161 that extends up from the seating surface 144 and an angled central edge 162 that extends at an angle from the vertical central edge 161 to the back surface 143 of the datum pillar 140. The locating ridge 160 can increase in width from the outer-most, front edge, where the locating ridge 160 can be narrower, to the back surface 143 of the datum pillar 140, where the locating ridge 160 can be wider.

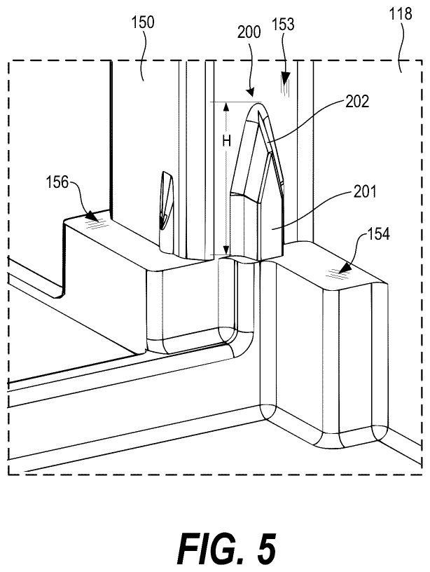

The locating ridge 160 is shown as an example in FIGS. 4A and 4B. The locating ridge 160 can vary in size, shape, and style in other embodiments. As examples, the height “H” of the locating ridge 160 can vary as compared to that shown. The height “H” of the locating ridge 160 can be selected to determine the extent of the mechanical interference between the PCB 130 and the locating ridge 160. The height “H” of the locating ridge 160 can be selected to control whether or not the locating ridge 160 interferes with (e.g., contacts) all of the layers of the PCB 130 along the locating edge 121 of the interlock notch 120, from the bottom surface to the top surface of the PCB 130, as described below with reference to FIG. 5. The shape of the locating ridge 160 can also vary as compared to that shown. The locating ridge 160 can be formed to have more rounded, or even flattened, outer surfaces rather than the relatively narrow outer edges of the vertical central edge 161 and the angled central edge 162. An example locating ridge with a flattened outer surface is described below with reference to FIG. 5. The position of the locating ridge 160 can also vary as compared to that shown. The locating ridge 160 can be located at other positions on the back surface 143 of the datum pillar 140.

The datum pillar 140 also includes a centering bumper 180, as shown in FIG. 4B. The centering bumper 180 can be formed as a rounded, semi-circular ridge of material that extends outwardly from a side surface of the datum pillar 140. The centering bumper 180 can include a rounded ridge 181 that extends up from the seating surface 146 and an angled edge 182 that extends at an angle from the rounded ridge 181 to the side surface of the datum pillar 140. The centering bumper 180 can help to position the PCB 130 centrally within the housing of the module 102, as described in further detail below.

FIG. 4C illustrates a top-down view of the detail view BB shown in FIG. 2B, and FIG. 4D illustrates a perspective view of the detail view BB shown in FIG. 2B. The PCB 130 is omitted from view in both FIGS. 4C and 4D, so that the locating ridge 170 can be shown. The locating ridge 170 is depicted as an example in FIGS. 4C and 4D, and the locating ridge 170 can vary in size, shape, and style in other embodiments and as described below. The locating ridge 170 may be formed as an angled ridge of material that extends outwardly from a surface of the datum pillar 150. The locating ridge 170 extends outwardly from a back surface 153 of the datum pillar 150. The back surface 153 of the datum pillar 150 extends in a plane that runs parallel to the datum surface 151 (see FIG. 2A) of the datum pillar 150.

The datum pillar 150 includes seating surfaces 154 and 156. A bottom surface of the PCB 130 can rest upon the seating surfaces 154 and 156 of the datum pillar 150, among other surfaces provided by the lower housing shell 114, when the PCB 130 is assembled in the module 102. The locating ridge 170 extends up to a height “H” from the seating surface 154. The locating ridge 170 includes a vertical (or substantially vertical) central edge 171 that extends up from the seating surface 154 and an angled central edge 172 that extends at an angle from the vertical central edge 171 to the back surface 153 of the datum pillar 150. The locating ridge 170 can increase in width from the outer edges of the vertical central edge 171 and the angled central edge 172, where the locating ridge 170 can be narrower, to the back surface 153 of the datum pillar 150, where the locating ridge 170 can be wider.

The locating ridge 170 is shown as an example in FIGS. 4C and 4D. The locating ridge 170 can vary in size, shape, and style in other embodiments. As examples, the height “H” of the locating ridge 170 can vary as compared to that shown. The height “H” of the locating ridge 170 can be selected to determine the extent of the mechanical interference between the PCB 130 and the locating ridge 170. The height “H” of the locating ridge 170 can be selected to control whether or not the locating ridge 170 interferes through (e.g., contacts) all the layers of the PCB 130 along the locating edge 123 of the interlock notch 122, from the bottom surface to the top surface of the PCB 130. The shape of the locating ridge 170 can also vary as compared to that shown. The locating ridge 170 can be formed to have more rounded, or even flattened, outer surfaces rather than the relatively narrow outer edges of the vertical central edge 171 and the angled central edge 172. An example locating ridge with a flattened outer surface is described below with reference to FIG. 5. The position of the locating ridge 170 can also vary as compared to that shown. The locating ridge 170 can be located at other positions on back surface 153 of the datum pillar 150.

As noted above, the locating ridges 160 and 170 of the datum pillars 140 and 150 can help to ensure an accurate position of the PCB 130 within the lower housing shell 114. When the PCB 130 is seated on the seating surfaces 144, 146, 154, and 156 of the lower housing shell 114, the locating ridges 160 and 170 can push against the locating edges 121 and 123 of the interlock notches 120 and 122, respectively. This mechanical interference can set the position of the PCB 130 accurately with respect to the lower housing shell 114. In turn, the leading edges of the contacts 136 and 137 in the row of contacts 134 can be accurately set to be the distance “D” from the datum surfaces 141 and 151 of the datum pillars 140 and 150, as shown in FIGS. 2A and 2B.

The datum pillar 150 can also includes a centering bumper 190, as shown in FIG. 4D. The centering bumper 190 can be formed as a rounded, semi-circular ridge of material that extends outwardly from a side surface of the datum pillar 150. The centering bumper 190 can include a rounded ridge 191 that extends up from the seating surface 156 and an angled edge 192 that extends at an angle from the rounded ridge 191 to the side surface of the datum pillar 150. The centering bumpers 180 (see FIG. 4B) and 190 can help to position the PCB 130 centrally within the housing of the module 102.

FIG. 5 illustrates a detail view of another example locating ridge 200. The locating ridge 200 is depicted as an example in FIG. 5, and the locating ridge 200 can vary in size, shape, and style in other embodiments. The locating ridge 200 can be relied upon as a replacement for one or both of the locating ridges 160 and 170 in the housing of the module 102. In the example shown in FIG. 5, the locating ridge 200 is a replacement of the locating ridge 170 and is part of the datum pillar 150. The locating ridge 200 is formed as an angled ridge of material that extends outwardly from a surface of the datum pillar 150. The locating ridge 200 extends outwardly from a back surface 153 of the datum pillar 150.

The locating ridge 200 extends up to a height “H” from the seating surface 154. The locating ridge 200 can be taller or larger in “H” than the locating ridge 170 shown in FIG. 4D, although the height “H” of the locating ridge 200 can vary in size. The locating ridge 200 includes a vertical (or substantially vertical) central surface 201 that extends up from the seating surface 154 and an angled central edge 202 that extends at an angle from the vertical central surface 201 to the back surface 153 of the datum pillar 150. The locating ridge 200 can be narrower at the vertical central surface 201 and wider at the back surface 153 of the datum pillar 150.

The vertical central surface 201 of the locating ridge 200 can be preferrable to the narrower, sharper corner of the vertical central edge 171 of the locating ridge 170 shown in FIG. 4D, in some cases. Additionally, the height “H” of the locating ridge 200 can be selected to control whether or not the locating ridge 200 contacts all the layers of the PCB 130. The shape of the locating ridge 200 can also vary as compared to that shown. For example, the vertical central surface 201 can be formed to have a rounded, rather than flat, surface. The locating ridge 200 can also be located at other positions on the back surface 153 of the datum pillar 150.

FIG. 6 illustrates the sectional view designated A-A in FIG. 2B. As shown in FIG. 6, a bottom surface 133B of the PCB 130 rests upon the seating surface 144 of the datum pillar 140, among other surfaces provided by the lower housing shell 114. The locating ridge 160 includes the vertical central edge 161 that extends vertically up from (e.g., substantially perpendicular to) the seating surface 144. The locating ridge 160 also includes the angled central edge 162, which extends at an angle from an end of the vertical central edge 161 to the back surface 143 of the datum pillar 140. The locating ridge 160 contacts and pushes against the locating edge 121 of the interlock notch 120 (see FIG. 3) of the PCB 130, to set the position of the PCB 130 accurately with respect to the lower housing shell 114.

The locating ridge 160 can vary in size. The height “H” of the locating ridge 160, for example, can vary as compared to that shown. The height “H” of the locating ridge 160 can be selected to determine the extent of the contact between the PCB 130 and the locating ridge 160. The height “H” of the locating ridge 160 can be selected to control whether or not the locating ridge 160 interferes through (e.g., contacts) all the layers of the PCB 130. In the example shown in FIG. 5, the height “H” of the locating ridge 160 is selected such that the locating ridge 160 contacts the bottom surface 133B of the PCB 130 and some of the internal layers of the PCB 130, but the locating ridge 160 does not contact or intersect with the top surface 133A of the PCB 130. It can be helpful to avoid contact with both the top surface 133A and the bottom surface 133B of the PCB 130 in some cases to avoid delamination of the PCB 130.

FIG. 7 illustrates another example lower housing shell 114A for the cable assembly 100 shown in FIG. 1A. The lower housing shell 114A includes a bottom wall 115A and side walls 116A and 118A. A datum pillar 140A is positioned along the side wall 116A, toward a front end of the lower housing shell 114A, and another datum pillar 142A is positioned further back along the side wall 116A. A datum pillar 150A is also positioned along the side wall 118A, toward the front end of the lower housing shell 114A, and another datum pillar 152A is positioned further back along the side wall 118A. The lower housing shell 114A can also include other datum pillars, at other locations, in addition to the datum pillars 140A, 142A, 150A, and 152A in some cases. A PCB can be designed to have interlock notches corresponding to the positions, shapes, sizes, etc., of the datum pillars 140A, 142A, 150A, and 152A, consistent with the concepts described herein.

The datum pillar 150A includes a centering bumper 180A, and the datum pillar 152A includes a locating ridge 160A. The centering bumper 180A is similar to the centering bumper 180 of the lower housing shell 114 shown in FIGS. 4A and 4B. The locating ridge 160A is also similar to the locating ridge 160 shown in FIGS. 4A and 4B. However, as compared to the lower housing shell 114, the centering bumper 180A and the locating ridge 160A can extend down to the bottom wall 115A of the lower housing shell 114A, because the lower housing shell 114A does not include the seating surfaces 144 and 146 of the lower housing shell 114. Additionally, the datum pillar 150A includes the centering bumper 180A on one side but does not include any locating ridge on any side. The datum pillar 152A includes the locating ridge 160A on one side but does not include any centering bumper on any side. Although not visible in FIG. 7, the datum pillar 140A includes a centering bumper, and the datum pillar 142A includes a locating ridge.

The lower housing shell 114A presents a different arrangement of datum pillars, centering bumpers, and locating ridges, as compared to the lower housing shell 114. Other variations are within the scope of the embodiments, including other numbers of datum pillars, at other locations, and other numbers (i.e., two (2), three (3) or more), positions, and arrangements of centering bumpers and locating ridges on each datum pillar can be relied upon. Overall, the mechanical interferences between the centering bumpers and locating ridges of a housing shell and the peripheral edge surface of a PCB can help to accurately set the location and position of the PCB within the housing shell.

Terms such as “top,” “bottom,” “side,” “front,” “back,” “right,” and “left” are not intended to provide an absolute frame of reference. Rather, the terms are relative and are intended to identify certain features in relation to each other, as the orientation of structures described herein can vary. The terms “comprising,” “including,” “having,” and the like are synonymous, are used in an open-ended fashion, and do not exclude additional elements, features, acts, operations, and so forth. Also, the term “or” is used in its inclusive sense, and not in its exclusive sense, so that when used, for example, to connect a list of elements, the term “or” means one, some, or all of the elements in the list.

Combinatorial language, such as “at least one of X, Y, and Z” or “at least one of X, Y, or Z,” unless indicated otherwise, is used in general to identify one, a combination of any two, or all three (or more if a larger group is identified) thereof, such as X and only X, Y and only Y, and Z and only Z, the combinations of X and Y, X and Z, and Y and Z, and all of X, Y, and Z. Such combinatorial language is not generally intended to, and unless specified does not, identify or require at least one of X, at least one of Y, and at least one of Z to be included.

The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

The above-described embodiments of the present disclosure are merely examples of implementations to provide a clear understanding of the principles of the present disclosure. Many variations and modifications can be made to the above-described embodiments without departing substantially from the spirit and principles of the disclosure. In addition, components and features described with respect to one embodiment can be included in another embodiment. All such modifications and variations are intended to be included herein within the scope of this disclosure.

At least the following is claimed:

1. A cable assembly, comprising:
a housing comprising a datum pillar, the datum pillar comprising a locating ridge extending from an outer surface of the datum pillar; and
a printed circuit board (PCB) positioned in the housing, the PCB comprising an interlock notch, wherein:
the datum pillar occupies open space within the interlock notch of the PCB; and
the locating ridge of the datum pillar applies a mechanical interference to a peripheral edge of the interlock notch of the PCB.

2. The cable assembly according to claim 1, wherein:
the PCB comprises a row of contacts;
the row of contacts comprises signal contacts and ground contacts;
a contact among the row of contacts comprises a leading contact edge; and
the locating ridge of the datum pillar sets a location of the leading contact edge of the contact with respect to a datum surface of the datum pillar.

3. The cable assembly according to claim 1, wherein the locating ridge comprises an angled central edge and a vertical central edge.

4. The cable assembly according to claim 3, wherein the vertical central edge extends up from a seating surface of the housing and the angled central edge extends at an angle from the vertical central edge to a surface of the datum pillar.

5. The cable assembly according to claim 1, wherein the locating ridge comprises an angled central edge and a vertical central surface.

6. The cable assembly according to claim 1, wherein:
the housing further comprises an upper housing shell and a lower housing shell;
the lower housing shell comprises a bottom wall and side walls that extend perpendicular to the bottom wall; and
the datum pillar is positioned along a side wall among the side walls of the lower housing shell.

7. The cable assembly according to claim 1, wherein:
the datum pillar comprises a first datum pillar;
the locating ridge comprises a first locating ridge extending from an outer surface of the first datum pillar;
the housing further comprises a second datum pillar; and
the housing further comprises a bumper extending from an outer surface of the second datum pillar.

8. The cable assembly according to claim 7, wherein:
the interlock notch comprises a first interlock notch positioned along a peripheral side edge of the PCB;
the PCB comprises a second interlock notch positioned along the peripheral side edge of the PCB; and
the first locating ridge and the bumper set the location of the PCB with respect to the housing based on a mechanical interference between the first locating ridge and the first interlock notch and a mechanical interference between the second locating ridge and the bumper.

9. The cable assembly according to claim 1, wherein the datum pillar further comprises a centering bumper extending from another outer surface of the datum pillar.

10. A cable assembly, comprising:
a housing comprising a datum surface and a locating ridge; and
a printed circuit board (PCB) positioned in the housing, wherein the locating ridge sets a location of the PCB with respect to the datum surface of the housing based on contact between the locating ridge and a peripheral edge of the PCB.

11. The cable assembly according to claim 10, wherein:
the PCB comprises a signal contact; and
the locating ridge sets a location of a leading contact edge of the signal contact with respect to the datum surface.

12. The cable assembly according to claim 10, wherein the locating ridge comprises an angled central edge and a vertical central edge.

13. The cable assembly according to claim 12, wherein the vertical central edge extends up from a seating surface of the housing and the angled central edge extends at an angle from the vertical central edge.

14. The cable assembly according to claim 10, wherein the locating ridge comprises an angled central edge and a vertical central surface.

15. The cable assembly according to claim 10, wherein the housing further comprises:
a first datum pillar positioned along a first side wall of the housing, the locating ridge extending from an outer surface of the first datum pillar;
a second datum pillar positioned along a second side wall of the housing; and
a second locating ridge extending from an outer surface of the second datum pillar.

16. The cable assembly according to claim 15, wherein the PCB further comprises:
a first interlock notch positioned along a first peripheral side edge of the PCB; and
a second interlock notch positioned along a second peripheral side edge of the PCB, wherein the first locating ridge and the second locating ridge set the location of the PCB with respect to the housing based on mechanical interferences between the first locating ridge and the second locating ridge and the first interlock notch and the second interlock notch, respectively.

17. The cable assembly according to claim 16, wherein:
the first datum pillar further comprises a first centering bumper extending from another outer surface of the first datum pillar; and
the second datum pillar further comprises a second centering bumper extending from another outer surface of the second datum pillar.

18. A cable assembly, comprising:
a housing comprising a locating ridge and a centering bumper; and
a printed circuit board (PCB) positioned in the housing, wherein the locating ridge and the centering bumper set a location of the PCB with respect to the housing based on contact between a peripheral edge of the PCB, the locating ridge, and the centering bumper.

19. The cable assembly according to claim 10, wherein:
the PCB comprises a signal contact; and
the locating ridge sets a location of a leading contact edge of the signal contact with respect to a datum surface of the housing.

20. The cable assembly according to claim 10, wherein the locating ridge comprises an angled edge.
